(19) United States
(12) Patent Application Publication
(10) Pub. No.: US 2017/0302091 A1
(43) Pub. Date: Oct. 19, 2017

(54) ELECTRIC ACTUATOR WITH PRE-HEATING

(71) Applicant: Robert Bosch GmbH, Stuttgart (DE)

(72) Inventors: Thomas Schaedlich, Kornwestheim (DE); Sven Bergmann, Stuttgart (DE)

(21) Appl. No.: 15/512,999

(22) PCT Filed: Aug. 5, 2015
(86) PCT No.: PCT/EP2015/068072

§ 371 Date: Mar. 21, 2017

(30) Foreign Application Priority Data
Sep. 23, 2014 (DE) 10 2014 219 211.0

(51) Int. Cl. H02J 7/00; B60L 3/00; H03K 3/017; B60L 11/18

(52) U.S. Cl. CPC H02J 7/0031; H02J 7/0045; B60L 11/1875; H03K 3/017; B60L 3/0046; B60L 2240/36; Y10S 903/903

(57) ABSTRACT

The invention relates to a method for operating an electrical network, in particular an onboard network of a vehicle, in particular of a hybrid vehicle (HEV), of a plug-in hybrid vehicle (PHEV) or of an electric vehicle (EV). Said network comprises a battery system, which contains a battery separation unit (10), with which a high-voltage battery (12) can be separated from a battery positive pole (18) and/or a battery negative pole (32) or from both battery poles (18, 32) of the on-board network. A main contactor and/or precharging contactor coil (22, 28, 36) of at least one electromagnetic switch (20, 24) is pre-heated. In the case of a pulse-width modulation signal control, the actuation takes place with a fraction (54), preferably 10% to 30%, of an activation pulse width. In the case of actuation by direct current signals, the main contactor and/or precharging contactor coils (22, 28, 36) are preheated according to the temperature in the interior of the electrical energy accumulator with heating gradients (62, 64, 66) chosen according to the temperature.

### BACKGROUND OF THE INVENTION

The invention relates to a method for operating an electrical network, in particular an on-board electrical network of a vehicle, such as, for example, of a hybrid vehicle or of an electric vehicle comprising a battery system which includes a battery disconnector unit. By means of this battery disconnector unit, an electrical energy accumulator can be disconnected from the on-board electrical network at a battery positive pole and/or at a battery negative pole.

Lithium ion battery systems are currently used most of the time in stationary applications such as, e.g., wind power stations, and in units used for emergency power supply, such as in mobile applications, such as, for example, in hybrid-electric vehicles (HEV) or electric vehicles (EV). Very high requirements are placed on such battery systems in respect of the usable energy content, the usable power, the level of charging-discharging efficiency, a non-presence of a memory effect, and on the reliability and, last but not least, on the service life.

In order to satisfy the requirements for a sufficiently high total voltage for supplying the electrical drive machine of hybrid electric vehicles or electric vehicles, approximately 100 or more individual battery cells are electrically connected in series or, to a partial extent, are also electrically connected in parallel in the high voltage traction batteries of said vehicles. In this case, a battery voltage of up to 600 volts can result.

This voltage is considerably higher than the touch voltage permitted for humans. In healthy adults, a life-threatening situation is considered to exist starting at a touch voltage of 50 volts of alternating current or 120 volts of direct current. In children and domestic animals, the touch voltage lies only at a maximum of 25 volts of alternating current or 60 volts of direct current.

Care must be taken to ensure that the life-threatening, high battery voltage of the battery poles is galvanically isolated in order to ensure that no current is consumed when the on-board electrical system of the vehicle is shut off and the vehicle is stationary, and to ensure that further damage—which may be serious—is avoided in the event of a malfunction outside or inside the electrical energy accumulator, and to ensure that rescue personnel are not endangered after an accident. For this safe operation, battery disconnector units are generally provided in high voltage battery systems, which units bring about a disconnection of the high voltage batteries from the on-board electrical system by shutting off their contactors or relays which are pulled in during operation of the high voltage battery system and thereby electrically connect the battery to the vehicle and the consumers. According to the present state of the art, the battery disconnector unit generally includes a fusible link which functions as a current-interruption device in the event of an overload. The battery disconnector units generally include the main contactors which are installed in the battery connecting leads. In addition, the battery disconnector unit includes a precharging circuit comprising a precharging contactor, which generally lies in series with a charging resistor, and current sensors. The current sensors are generally a Hall current sensor and a shunt current sensor.

In most cases, the main contactors are very powerful, large, and relatively expensive electromechanical switches. The requirement on these switches is that they must be capable of reliably interrupting a short-circuit current in the magnitude of multiple 1000 amperes. The coils of the main contactors are very low-resistance primarily in extreme cold, i.e., at temperatures of −30° C. and lower. In this case, a very high switch-on current could flow, which a typical electronic driver stage would in no way be capable of delivering. Such a switch-on current could result in the destruction of the electronic output stages. The driver stages would need to be designed with greater complexity merely for the low-temperature condition, which results in considerably higher costs, however.

US 2008/0218928 A1 relates to a coil-control device of a solenoid switch. A coil-actuation device replaces the main components of an analog circuit with those of a digital circuit comprising a pulse-width modulation control unit having low consumption. As a result, the number of analog components is reduced, the energy consumption is lowered, and a constant voltage is generated. This is present at the coil; simultaneously, a coil reverse-current flows, whereby the occurrence of faults and damage is reduced and, in addition, further damage to the circuit is prevented.

US 2013/0009464 A1 relates to a system and a method for controlling a battery pack switch. The coil of the switch is controlled via a high-power unit.

### SUMMARY OF THE INVENTION

According to the invention, a method is provided for operating an electrical network, in particular an on-board electrical network of a vehicle, for example, of a hybrid vehicle or of an electric vehicle comprising a battery system which includes a battery disconnector unit. By means of this battery disconnector unit, an electrical energy accumulator can be disconnected from the on-board electrical network at a battery positive pole and at a battery negative pole or at both battery poles simultaneously. According to the method provided according to the invention, coils for actuating at least one electromechanical switch are preheated via an electrical energy accumulator. In the present context, the at least one electromechanical switch is a main contactor switch for a battery positive pole, a precharging contactor switch, and a main contactor switch for a battery negative pole.

The preheating of the coils takes place either in the case of a pulse-width modulated signal control by actuating the coils with a fraction, preferably 10% to 30%, of an activation pulse width. Therefore, a low duty cycle is selected. In the case of the use of direct current signals, a preheating of the coils for actuating the at least one electromechanical switch takes place according to the ambient temperature with heating gradients selected according to the temperature.

Due to the solution provided according to the invention, when the on-board electrical system is switched on in very cold conditions, a preferably rapid preheating of the coil actuating the at least one electromechanical switch is achieved. The preheating of the coils takes place with an electric current which induces the at least one electromechanical switch, which is also referred to as a contactor, to not quite close. If the at least one electromechanical switch is intended to be closed, however, the coils preheated according to the method provided according to the invention are actuated with a current which definitely and reliably induces the at least one electromechanical switch to close.

In the case of the use of a pulse-width modulation signal control, an activation pulse width is set, for example, at temperatures in the magnitude of −30° C. and below, which does not quite overtax the power of the driver stage, i.e., for example, 10% of the activation pulse width. An activation pulse width is considered to be the pulse width at which the coil of the at least one electromechanical switch should be activated when it is intended to be closed. Since the current can rise to a very high level at this temperature and at low coil resistances given a 10% activation pulse width, to name one example of a fraction, the duty cycle within the scope of the pulse width modulation in this case is therefore 1:9.

In the method provided according to the invention, the duty cycle can be increased when the coil for actuating the at least one electromechanical switch has reached a higher temperature. At a higher coil temperature and given an increased duty cycle, the same preheating output can be fed into the coil. The current which flows in this case is limited by the higher coil resistance. The preheating always takes place only so far, however, that, on the one hand, the output stage remains intact, i.e., said output stage can reliably deliver the preheating current and, on the other hand, the at least one electromechanical switch does not quite close.

The information regarding an internal temperature T_{I} of a battery pack or a battery module is known in the case of a traction battery pack by the battery management system or by a battery module controller. The coil temperature, which the coil has before actuation of the electromechanical switch, results from the relationship

T_{S}=T_{I}+ΔT,

in which
ΔT: temperature in the coil
T_{I}: internal temperature of the battery pack

According to this relationship, the coil preheating control sets the coil temperature T_{S} and can set the maximum preheating output possible for rapid preheating, which is selected precisely such that the at least one electromechanical switch does not close.

In modern output stage ICs (integrated circuits), the current which said ICs give off, as well as the temperature of said ICs, are known. Therefore, such integrated circuits are capable of automatically regulating their power loss to just barely permissible values, of limiting their power loss to these values, and to move as close to an activation duty cycle as possible. If the duty cycle lies below this activation duty cycle, it is ensured, on the one hand, that the coil is preheated to a maximum extent and the preheating time is minimized and, on the other hand, that the at least one electromechanical switch does not quite close.

On the other hand, if it is desired that an electromechanical switch whose actuation coils were preheated by means of the method according to the invention, via pulse-width modulation, reliably closes, the activation pulse width is selected accordingly. The activation pulse width or the duty cycle is set in such a way that, for each coil temperature, a reliable and rapid closing of the at least one electromechanical switch is ensured.

As an alternative to the pulse-width modulated signal actuation, the coils can also be heated via a direct-current preheating using a corresponding current regulation. According to this alternative embodiment of the method provided according to the invention, a current regulation takes place, wherein a slow heating of the coil of the relevant at least one electromechanical switch takes place during a start of preheating, for example, at an internal battery pack temperature T_{I}=−30° C. As the coil heating increases, however, an increasing direct current is delivered. The initially slowly proceeding current increase results from the fact that an output-stage power loss in the active control mode is that much greater, the lower the load resistance is. Therefore, the preheating current is increased slowly, so that the coil of the at least one electromechanical switch has time to heat up. Once the coil has been heated, for example, after a preheating time of a few seconds, the current used for the preheating can be increased to a maximum non-activation value; the preheating current remains at this value. The higher the internal temperature T_{I} of the battery pack or battery module, relative to the beginning of the preheating, the more steeply the current increase of the preheating current can take place given a maximum non-activation value, without the at least one electromechanical switch closing. If the closing of said switch is required, however, the activation current is set to, for example, Iₘₐₓ, at which a reliable closing of the at least one electromagnetic switch is ensured.

Due to the solution provided according to the invention, it is possible, in the case of a closed electromagnetic switch, i.e., a closed contactor contact, to reduce the coil excitation both in the case of the pulse-width modulation actuation, as well as in the case of the direct-current actuation to such a low extent that a holding excitation, which is considerably lower than the initial excitation, has reliably not yet been fallen below. As a result, it is possible to reduce the power loss of the coil, to limit its temperature to permissible values, and to hold it to these values. Due to the solution provided according to the invention, a method is provided, with which the coil temperature of power contactors, i.e., electromechanical switches within the scope of a battery disconnector unit in traction batteries in the drive train of hybrid vehicles or electric vehicles can be increased as rapidly as possible, which takes place while remaining within power-loss limits which can be accommodated by the output stage ICs. Due both to the pulse-width modulation method and the direct-current preheating, in the case of low outside temperatures in extreme cold, a preferably rapid preheating of the coils for actuating at least one electromechanical switch with electrical energy can be achieved, which energy induces the at least one electromagnetic switch to not quite close. If the at least one electromechanical switch is intended to be closed, however, the previously preheated coils are actuated with an increased current which reliably induces the at least one electromechanical switch to close. As a result, it is possible to optimize the output-stage design of the output stage ICs and to reduce costs.

### BRIEF DESCRIPTION OF THE DRAWINGS

The invention is described in greater detail in the following with reference to the drawings.

In the drawings:

FIG. 1 shows a simplified diagram of an electrical energy accumulator comprising a battery disconnector unit,

FIG. 2 shows a simplified diagram of the preheating signals of contactor coils with pulse-width modulated actuation,

FIG. 3 shows a simplified diagram of a preheating of contactor coils by means of direct current signals and current regulation,

FIG. 4 shows a schematic representation of a control circuit comprising a comparator,

FIG. 5 shows a first circuit arrangement for actuating an electromechanical switch, and

FIG. 6 shows a circuit arrangement having a high-side output stage and a low-side output stage.

### DETAILED DESCRIPTION

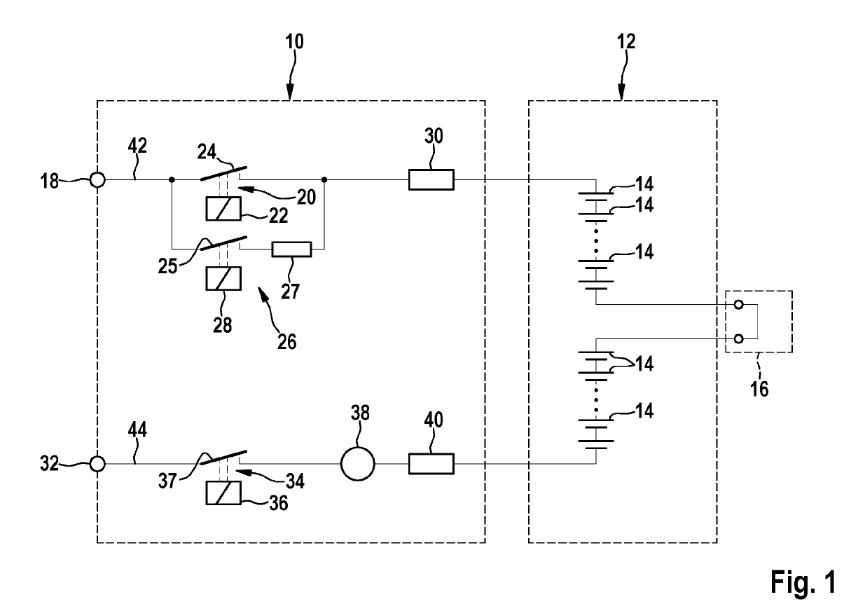

The representation according to FIG. 1 shows a simplified diagram of an electrical energy accumulator comprising a battery disconnector unit.

The battery disconnector unit 10 represented in FIG. 1 is connected to a high voltage battery 12. Said high voltage battery includes a battery pack or a battery module, within which a number of battery cells 14 is electrically interconnected. The high voltage battery 12 according to the representation in FIG. 1 further includes a service plug 16.

The battery disconnector unit 10, which is labeled with reference number 10, includes a battery positive pole 18 and a battery negative pole 32. The battery disconnector unit 10 contains, in a first battery connecting lead 42, a main contactor 20 for the battery positive pole 18. The main contactor 20 includes an electromechanical switch 24 which is referred to as a main contactor switch for the battery positive pole 18 and is actuated via a main contactor coil 22. A precharging contactor 26 is connected in parallel to the main contactor 20, and a charging resistor 27 is situated in series with said precharging contactor. The precharging contactor 26 has a separate precharging contactor coil 28 which actuates a precharging contactor switch 25. The precharging contactor 26 is situated in parallel to the main contactor 20. A current-interruption unit 30 is situated in the first battery connecting lead 42. Said current-interruption unit is generally designed as a fusible link which melts in the event of an overload, i.e., an impermissibly high current.

A second battery connecting lead 44 extends from the battery negative pole 32. Said second battery connecting lead accommodates a main contactor 34 for the battery negative pole 32. The electromechanical switch thereof, i.e., the main contactor switch 37 for the battery negative pole 32, is actuated by means of a main contactor coil 36. Two current sensors 38, 40 are situated in the second battery connecting lead 44 in series with respect to the main contactor 34 for the battery negative pole 32. For reasons of redundancy, these are a Hall current sensor 38 and a shunt current sensor 40 situated in series with respect thereto.

The two battery connecting leads 42, 44, in which the main contactor 20 or 34, respectively, are located, extend through the battery disconnector unit 10 to the high voltage battery 12. The main contactors 20, 34 and the precharging contactor 26 are electromechanical switches.

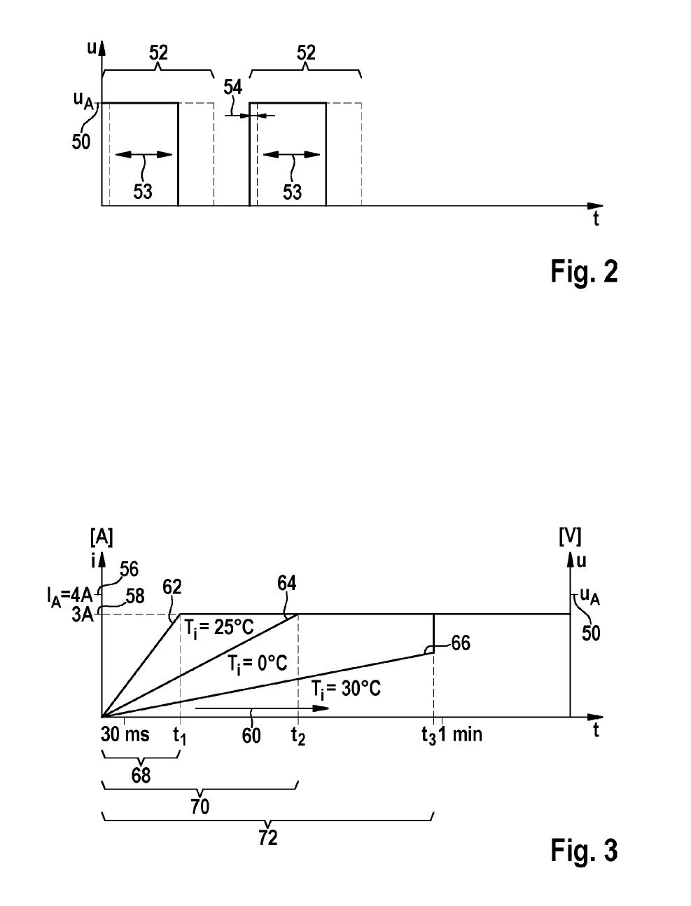

The representation according to FIG. 2 shows a simplified diagram of preheating of the coils for actuating the contactors by means of pulse-width modulated actuation.

In FIG. 2, the voltage is plotted with respect to time. An activation voltage u_{A} is identified by reference number 50. An activation pulse width, which is labeled with reference number 52 and is shown here for an outside temperature of −30° C., is set accordingly at a driver stage. In the exemplary embodiment shown, a fraction 54 corresponds to a fraction of 10% of the total activation pulse width of 52. The fraction 54 according to the representation in FIG. 2 can be selected between 10% and 30%. Since the current could rise very high at an outside temperature of −30° C. and given a low coil resistance, the duty cycle for the pulse-width modulated actuation must be selected very low. At an elevated temperature of the coils 22, 28, 36, as represented in FIG. 1, the duty cycle can therefore be increased, in order to feed the same preheating power into the coils 22, 28, 36 for actuating the main contactors 20, 34 and the precharging contactor 26. The maximum current which can flow is limited by the higher coil resistance.

Based on the information regarding the internal temperature of a battery pack of a high voltage battery 12, as represented in FIG. 1, the following relationship yields a coil temperature T_{S}:

T_{S}=T_{I}+ΔT,

in which
T_{I}: internal temperature of the battery pack
ΔT: temperature increase of the coil due to the holding current

The temperature difference ΔT results from the power loss in the particular main contactor coils 22, 36 and in the precharging contactor coil 28, which output is known to an actuation microcontroller on the basis of the duty cycle which was set. The coil preheating control sets the coil temperature T_{S}, and so the maximum possible preheating output for a rapid preheating can be set, at which the contacts of the electromechanical switches, i.e., the main contactor switch 24 for the battery positive pole 18, the main contactor switch 37 for the battery negative pole 32, and the precharging contactor switch 25, do not quite close.

In the case of modern output stage ICs, the current which said ICs give off, as well as the temperature, are known to the microcontroller. Due to the presence of this information, such integrated circuits are capable of automatically regulating and limiting their power loss, and of moving said power loss as close as possible to the activation duty cycle, i.e., to the duty cycle at which the contacts of the electromechanical switches, i.e., the main contactor switch 24 for the battery positive pole 18, close the main contactor switch 37 for the battery negative pole 32 and the precharging contactor switch 25. If this or these corresponding electromechanical switches are intended to be closed, however, by means of the preheated main contactor coil 22, the preheated main contactor coil 36 and/or the preheated precharging contactor coil 28, the activation pulse width 52 is set accordingly at the output stage IC. Said activation pulse width must be dimensioned for each coil temperature in such a way that said activation pulse width is ensured a reliable and rapid closing of the main contactor switch 24 for the battery positive pole 18 and/or of the main contactor 34 for the battery negative pole 32 and/or of the precharging contactor switch 25 for any temperature of the main contactor coil 22 actuating the electromagnetic switches, i.e., the main contactor switch 24 for the battery positive pole 18, the main contactor switch 37 for the battery negative pole 32 and/or the precharging contactor switch 25, the main contactor coil 36 and the precharging coil 28.

After the electromechanical switch has been actuated, the activation current can be lowered to the holding current, wherein the holding current is set via a corresponding holding duty cycle. The holding duty cycle is labeled with reference number 53 in FIG. 2.

A preheating of the main and precharging contactor coils by direct current signals is discussed in greater detail in association with FIG. 3.

In the case of a preheating controlled by means of direct current signals, given a battery pack temperature of T_{I}=−30° C.—as an example—at the beginning of preheating, a direct current is delivered, which increases slowly as the coil heating increases. A slowly occurring current increase results from the fact that an output-stage power loss in the active control mode is that much greater, the lower the present load resistance is. For this reason, the preheating current I is slowly increased, so that the main contactor and precharging contactor coils 22, 28 and 36 have time to heat up. Once the main contactor and precharging contactor coils 22, 28, 36 have been heated, which has occurred after one minute, for example, the preheating current I can be increased to a maximum non-activation current value 58. The maximum non-activation current value 58 in this case is lower than the activation current I_{A} which is labeled with reference number 56 in FIG. 3. According to the representation in FIG. 3, this current for the maximum non-activation current value 58 remains at 3 amperes, for example. The higher the internal temperature T_{I} of the electrical energy accumulator is, for example, T_{I}=0° C. and T_{I}=30° C. at the beginning of preheating, the more steeply the current increase can occur, up to an increase of the maximum non-activation value 58 of, for example, I=3 amperes. In this example, the activation current I_{A} is 4 amperes. Different heating gradients 62, 64, 66 for the heating current are shown in FIG. 3 for battery-pack internal temperatures of T_{I}=25° C., T_{I}=0° C., and T_{I}=−30° C. The preheating time is labeled with reference number 60. Different preheating times 68, 70, 72 result for the different heating gradients 62, 64, 66, respectively, depending on the different temperatures T_{I} of the high voltage battery 12. Different preheating times 68, 70, 72 are labeled with t₁, t₂ and t₃ in the diagram according to FIG. 3.

Due to the solution provided according to the invention, a preheating of coils for actuating electromagnetic switches, i.e., the main contactor switch 24 for the battery positive pole 18, the main contactor switch 37 for the battery negative pole 32 and/or the precharging contactor switch 25, can be represented, which can be depicted both via pulse-width modulated actuation and via direct-current control. In both actuation methods for preheating the main contactor and precharging contactor coils 22, 28, 36, it is possible for the temperature of the main contactor and precharging contactor coils 22, 28, 36 in traction batteries in the drive train of electric or hybrid vehicles to increase as fast as possible, in particular in very cold conditions, wherein the power loss limits of utilized stepped circuits are reliably complied with.

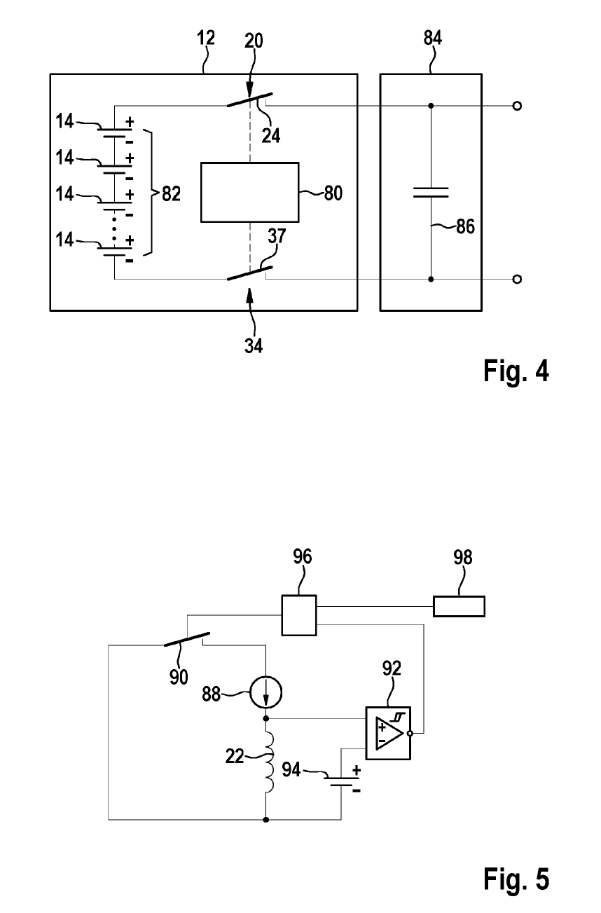

The representation according to FIG. 4 shows a schematic arrangement of a circuit actuation of electromagnetic switches by a battery control unit.

A battery control unit 80 schematically represented in FIG. 4 coordinates the tasks to be carried out in the high voltage battery 12. The high voltage battery 12 includes a number of individual battery cells 14 which are interconnected in a series circuit 82. The tasks of the battery control unit 80 include detecting battery cell voltages and battery cell temperatures, calculating a SOC (state of charge) and a SOH (state of health), and implementing safety functions, such as, for example, an insulation resistance measurement. The battery control unit 80 also provides an interface to the vehicle, whether it is a hybrid vehicle (HEV), a plug-in hybrid vehicle (PHEV), or an electric vehicle (EV). In addition, the battery control unit 80 controls the electromechanical switches, which were already represented in FIG. 1 and which are in the form of the main contactor switch 24 for the battery positive pole 18 and the main contactor switch 37 for the battery negative pole 32. If the high voltage battery 12 is in a safe state and the vehicle requests that the high voltage battery 12 be connected, the two main contactors 20 and 34 are connected, after an intermediate circuit 84 represented in FIG. 4 has been brought to the same voltage level as the voltage of the high voltage battery 12.

It is also clear from the representation according to FIG. 4 that the intermediate circuit 84 includes at least one capacitor 86. A design of a high-side or a low-side output stage generally takes place with consideration for the maximum activation current which is necessary and which is required for actuating the two main contactors 20 and 34. Since the coil resistance of the main contactor coils 22 and 36 assumes its minimum value at low temperatures, the high-side and low-side output stages must be dimensioned for a maximum activation current at this low temperature. The increase in the activation current at a low temperature in the magnitude of −40° C. relative to room temperature can lie in the magnitude of up to 40%. In order to utilize output stages which, in this case, do not deliver the necessary activation current and can be designed smaller, the main contactor coils 22 and 36 must be preheated as described above in association with FIGS. 1 to 3. This can take place either within the scope of the above-described pulse-width modulation method or by means of a preheating of the main contactor coils 22, 36 depending on the ambient temperature using temperature-dependent, selected heating gradients 62, 64, 66 (see FIG. 3). The main contactor coils 22, 36 are brought to a defined resistance value via a heating control, as described above. A heating element required therefor can be integrated separately into the main contactor 20 or 34, or the main contactor coils 22 or 36, respectively, can themselves be used as heating elements. In particular, a regulation monitors the temperature-dependent resistance of the main contactor coils 22 and 36, in order to terminate the heating phase in a defined manner and to initiate an activation phase of the two main contactors 20 and 34. The main contactor coils 22 and 36 are supplied during the heating phase by means of a constant current which is delivered by a constant-current source 88 (see FIG. 5). The current value delivered by the constant-current source 88 is selected in such a way that said current value lies below the value for the activation current of the two main contactors 20 and 34.

FIG. 5 shows a circuit, in which the main contactor coil 22 is preheated via the constant-current source 88. A switch 90 is closed. The current delivered by the constant-current source 88 is selected in such a way that the main contactor 20 for the battery positive pole 18 definitely does not switch, i.e., the current delivered by the constant-current source 88 lies below the activation current 56 of the main contactor 20. The power loss resulting from the coil resistance heats the main contactor coil 22. As the temperature of the main contactor coil 22 increases, the coil resistance of said coil increases. A temperature-dependent voltage l₁·R_{coil} can be measured by means of the main contactor coil 22. By means of a comparator 92, this voltage, which drops across the main contactor coil 22, is compared to a reference voltage 94. If a threshold is exceeded, the switch 90 is opened via the logic unit 96 which is connected not only to the output of the comparator 92, but also to an input of a trigger 98. Via the logic unit 96 (gate), trigger signals are combined with one another during opening and closing of the switch 90. In order to obtain a lead time for the heating phase, the heating phase can already be started by an external trigger event, such as, for example, the opening of the driver's door or the unlocking of the vehicle. A corresponding logical trigger signal starts the heating phase. The comparator 92 having a hysteresis function terminates the heating process via the logic unit 96 by applying a low level. The low level is, in particular, an inverted output signal. The activation phase for the two main contactors 20 and 34 can be started in this instant.

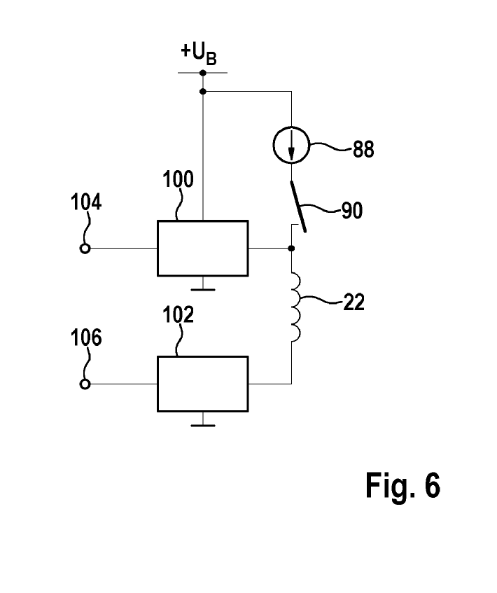

FIG. 6 shows a circuit combination having a high-side switch 100 and a low-side switch 102.

FIG. 6 shows that the main contactor coil 22 can be preheated by way of activating a low-side switch 102 and closing the switch 90. If the preheating has been terminated by means of a corresponding measurement of the coil voltage, the switch 90 is opened again and the high-side output stage delivers the activation current for actuating the main contactor coil 22 by means of an interconnected high-side switch 100 via a supply voltage +U_{B}. The reference numbers 104 and 106 each label signal taps of the high-side switch 100 and of the low-side switch 102.

The constant-current source 88 represented in FIG. 6 can be designed in such a way that said source is capable of delivering not only a preheating current for the main contactor coils 22 and 36, but also the holding current thereof. Therefore, the constant-current source 88 also takes over the task of providing the holding current, after completion of the activation phase with the activation current 56. The holding current required for holding one of the switches 24, 25, 37 is less than the activation current in this case. The comparator 92 having a hysteresis function as well as the logic unit 96 can also be implemented by means of a microcontroller, an AD converter, or comparable analog-digital circuits.

The invention is not limited to the exemplary embodiments described here or to the aspects emphasized therein. Rather, a plurality of modifications, which do not go beyond the normal abilities of a person skilled in the art, are possible within the scope indicated by the claims.

1. A method for operating an electrical network, comprising a battery system which includes a battery disconnector unit (10), configured to disconnect a high voltage battery (12) from the electrical network at a battery positive pole (18) and/or a battery negative pole (32) or at both battery poles (18, 32), including the following method steps:
preheating main contactor and/or precharging contactor coils (22, 28, 36) for actuating at least one electromechanical switch (20, 34),
wherein in the case of a pulse-width modulation signal control, setting a fraction (54), of an activation pulse width (52),
or
in the case of an actuation by direct current signals, preheating the main contactor and/or precharging contactor coils (22, 28, 36) according to an ambient temperature with heating gradients (62, 64, 66) selected according to the ambient temperature.

2. The method as claimed in claim 1, characterized in that a temperature T_{S} of the main contactor and/or precharging contactor coils (22, 28, 36) is determined according to the relationship:
T_{S}=T_{I}+ΔT
in which:
T_{S}: temperature of the main contactor and/or precharging contactor coils (22, 26, 36)
T_{I}: internal temperature of the high voltage battery (12)
ΔT: temperature increase due to the preheating current.

3. The method as claimed in claim 1, characterized in that a power loss of an output stage IC is limited to a maximum permissible power loss, and a duty cycle lies below an activation duty cycle for the main contactor and/or precharging contactor coils (22, 28, 36), at which the main contactor and/or precharging contactor coils (22, 28, 36) close the electromechanical switches (20, 34).

4. The method as claimed in claim 1, characterized in that an increasing direct current I flows as the coil heating increases starting at the beginning of the preheating, in the case of actuation by direct current signals.

5. The method as claimed in claim 4, characterized in that, depending on the heating of the main contactor and/or precharging contactor coils (22, 28, 36), the direct current I increases to a maximum non-activation value (58), at the value of which the direct current I remains limited.

6. The method as claimed in claim 1, characterized in that the heating gradients (62, 64, 66) for the main contactor and/or precharging contactor coils (22, 28, 36) are set based on an internal temperature T_{I} of the high voltage battery (12).

7. The method as claimed in claim 1, characterized in that the power loss of the main contactor and/or precharging contactor coils (22, 28, 36) is reduced and the temperature of the main contactor and/or precharging contactor coils (22, 28, 36) remains limited.

8. The method as claimed in claim 1, characterized in that a preheating current for heating the main contactor and/or precharging contactor coils (22, 28, 36) and a holding current are provided by a constant-current source (88).

9. The method as claimed in claim 1, characterized in that a voltage dropping across the main contactor and/or precharging contactor coil (22, 28, 36) is compared in a comparator (92) with a reference voltage (94) and a switch (90) is actuated for switching the constant-current source (88) on or off based on the comparison.

10. The method as claimed in claim 1 wherein the method is implemented for a high voltage battery (12.

11. The method as claimed in claim 1, wherein the electrical network is an on-board electrical network of a vehicle.

12. The method as claimed in claim 11, wherein the vehicle is a hybrid vehicle.

13. The method as claimed in claim 11, wherein the vehicle is an electric vehicle.

14. The method as claimed in claim 1, wherein the fraction (54) of the activation pulse width (52) is 10% to 30%.

15. The method as claimed in claim 10, wherein the high voltage battery (12) is a traction battery of a hybrid vehicle (HEV).

16. The method as claimed in claim 10, wherein the high voltage battery (12) is a traction battery of a plug-in hybrid vehicle (HEV).

17. The method as claimed in claim 10, wherein the high voltage battery (12) is a traction battery of an electric vehicle (EV).
